(19) United States
(12) Patent Application Publication
(10) Pub. No.: US 2026/0262492 A1
(43) Pub. Date: Sep. 3, 2026

(54) SEMICONDUCTOR DEVICE

(71) Applicant: Minebea Power Semiconductor Device Inc., Hitachi-shi, Ibaraki (JP)

(72) Inventor: Toshimitsu NOGUCHI, Hitachi-shi (JP)

(21) Appl. No.: 19/491,238

(22) PCT Filed: Feb. 15, 2024
(86) PCT No.: PCT/JP2024/005263

§ 371 Date: Dec. 8, 2025

(30) Foreign Application Priority Data
Jun. 29, 2023 (JP) 2023-106565

(51) Int. Cl. H10W 40/20; H10W 40/22; H10W 70/40; H10W 90/00; H10W 90/10

(52) U.S. Cl. CPC H10W 40/235; H10W 40/22; H10W 70/461; H10W 90/10; H10W 90/811

(57) ABSTRACT

A semiconductor device has a high insulation property and heat dissipation performance. The semiconductor device includes a semiconductor element, a lead frame that has conductivity and is connected to the semiconductor element, and a sealing resin that seals the semiconductor element and the lead frame. A heat conductive part has an insulation property and is formed of a ceramic compact. Part of the heat conductive part is sealed with the sealing resin, and the heat conductive part is connected to the lead frame inside the sealing resin. Another part of the heat conductive part is exposed from the sealing resin. This enables heat generated in the semiconductor element to radiate to the outside via the lead frame and the heat conductive part.

### TECHNICAL FIELD

The present invention relates to a semiconductor device.

### BACKGROUND ART

For example, Patent Literature 1 to Patent Literature 3 each disclose a semiconductor device in which semiconductor elements and lead frames are sealed with a sealing resin.

FIG. 1 of Patent Literature 1 describes a structure that semiconductor chips (1) and lead frames (5) are sealed with a resin-sealing package (4), and an attachment hole is provided at the center.

FIG. 1 and paragraphs 0018, 0019, and 0026 to 0028 of Patent Literature 2 describe a structure that a first semiconductor element (101) and a second semiconductor element (102), and a lead frame (108) including a die pad (121) are sealed with a mold resin (109), and an insulating sheet (110) is exposed to the outside of the mold resin (109). Furthermore, paragraph 0029 of Patent Literature 2 describes that the insulating sheet (110) has a thermal conductivity higher than a thermal conductivity of the mold resin (109), the insulating sheet (110) includes an insulating layer, the insulating layer includes a matrix made of a resin, and fillers made of ceramic having a high thermal conductivity, and the fillers are dispersed in the matrix.

FIG. 1 and paragraphs 0011 to 0016 of Patent Literature 3 describe a structure that a semiconductor element (24), a main terminal (20), and a heatsink (12) mainly containing Cu or Al as a main component are sealed with a resin (39), a lower surface of the heatsink (12) is exposed from the resin (39), and an insulating sheet (40) is attached to the lower surface of the heatsink (12). Paragraph 0015 of Patent Literature 3 describes that the insulating sheet (40) includes a first film (42) and a second film (44), and a material of the insulating sheet 40 is formed of a material that has both an electrical insulation property and heat dissipation performance and is, for example, a ceramic material.

### CITATION LIST

### Patent Literature

Patent Literature 1: Japanese Patent Application Publication No. 2002-26245

Patent Literature 2: Japanese Patent Application Publication No. 2020-181917

Patent Literature 3: WO 2016/006054

### SUMMARY OF INVENTION

### Technical Problem

However, in a case of the structure described in Patent Literature 1, heat is radiated through the resin-sealing package (4), and therefore there is a problem that the heat dissipation performance is not so high. Furthermore, if a highly heat conductive resin to which fillers are added is used to enhance the heat dissipation performance, there is a problem that flowability and a filling property at a time of molding lower. Furthermore, if the resin-sealing package (4) on a side that comes into contact with other members at a time of attachment is formed thin to enhance the heat radiation performance, there is a problem of disadvantages from a viewpoint of the filling property and the dielectric withstand voltage at the time of molding.

In the case of the structure described in Patent Literature 2, the insulating sheet (110) has a structure that ceramic fillers are dispersed in a resin matrix, and therefore there is a problem that thermal conductivity of the insulating sheet (110) is inferior to that of a ceramic compact. Furthermore, when the fillers are added, the flowability and the filling property deteriorate, and therefore there is a probability that a void is produced, and there is a probability that discharging occurs at the void portion at a high voltage and a breakdown voltage lowers.

The structure described in Patent Literature 3 is a structure that the lower surface of the conductive heatsink (12) is exposed from the resin (39), and therefore there is a problem that the insulating sheet (40) made of a ceramic material or the like needs to be attached to the lower surface of the heatsink (12).

A problem to be solved by the present invention is to provide a semiconductor device that has a high insulation property and heat dissipation performance.

### Solution to Problem

To solve the above problem, a semiconductor device according to the present invention includes: a semiconductor element; a lead frame that has conductivity and is connected to the semiconductor element; a sealing resin that seals the semiconductor element and the lead frame; a heat conductive part that has an insulation property and is formed of a ceramic compact, part of the heat conductive part is sealed with the sealing resin, the heat conductive part is connected to the lead frame inside the sealing resin, and other part of the heat conductive part is exposed from the sealing resin.

### Advantageous Effects of Invention

According to the present invention, it is possible to implement a semiconductor device that has a high insulation property and heat dissipation performance.

### BRIEF DESCRIPTION OF DRAWINGS

FIG. 1 is a top perspective view of a semiconductor device according to Embodiment 1.

FIG. 2 is a back view of the semiconductor device according to Embodiment 1.

FIG. 3 is a cross-sectional view taken along line A-A′ in FIG. 1.

FIG. 4 is a cross-sectional view illustrating a state where the semiconductor device according to Embodiment 1 has been attached.

FIG. 5 is a top perspective view of the semiconductor device according to Embodiment 2.

FIG. 6 is a cross-sectional view taken along line B-B′ in FIG. 5.

FIG. 7 is a top perspective view of the semiconductor device according to Embodiment 3.

FIG. 8 is a back view of the semiconductor device according to embodiment 3.

FIG. 9 is a cross-sectional view taken along line C-C′ in FIG. 7.

FIG. 10 is a cross-sectional view illustrating a state where the semiconductor device according to Embodiment 3 has been attached.

FIG. 11 is a top perspective view of the semiconductor device according to Embodiment 4.

FIG. 12 is a back view of the semiconductor device according to Embodiment 4.

FIG. 13 is a cross-sectional view taken along line D-D′ in FIG. 11.

FIG. 14 is a cross-sectional view illustrating a state where the semiconductor device according to Embodiment 4 has been attached.

### DESCRIPTION OF EMBODIMENTS

Hereinafter, embodiments of the present invention will be described with reference to the drawings. In each drawing and in each embodiment, identical reference symbols have been allocated to identical or similar constituent components, and duplicate description thereof has been omitted.

### Embodiment 1

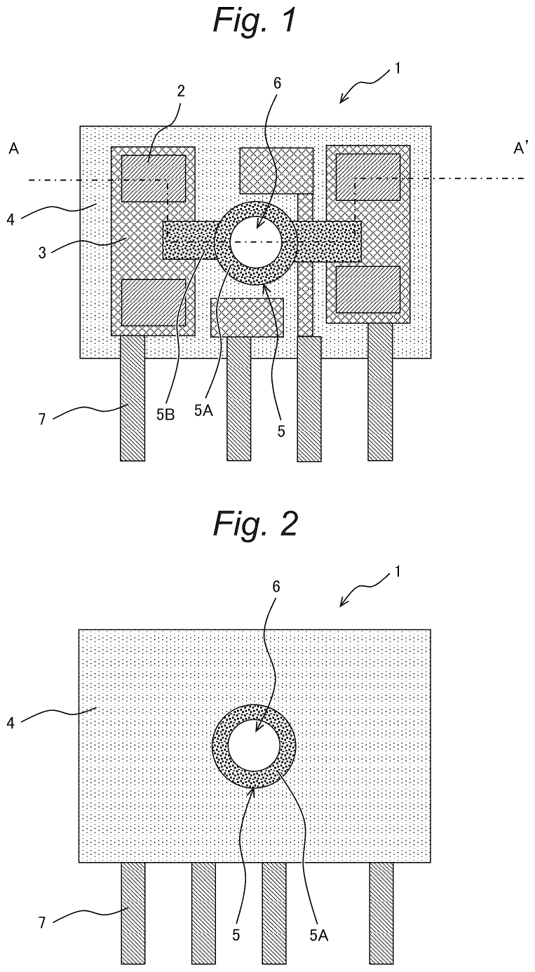

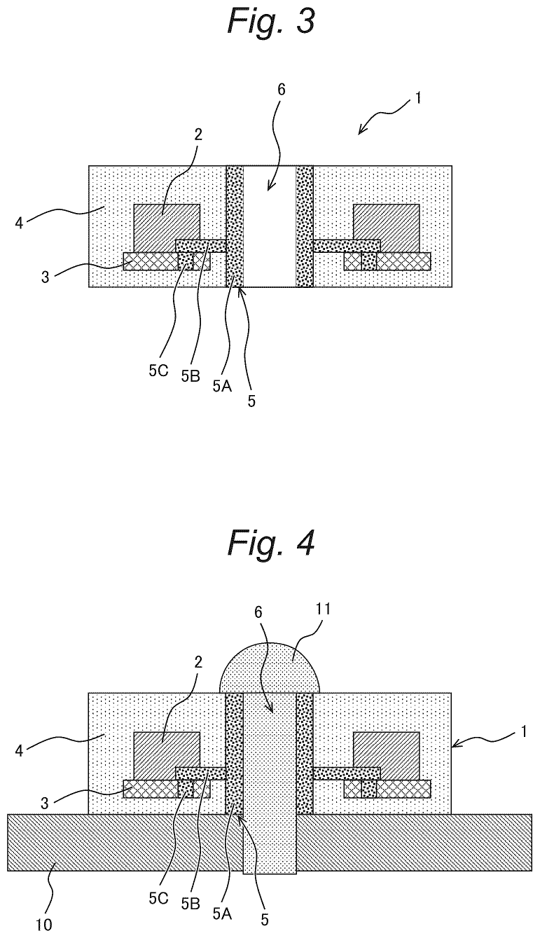

FIG. 1 is a top perspective view of a semiconductor device according to Embodiment 1. FIG. 2 is a back view of the semiconductor device according to Embodiment 1. FIG. 3 is a cross-sectional view taken along line A-A′ in FIG. 1. Note that FIG. 1 illustrates a perspective view of the internal structure of a sealing resin 4.

A semiconductor device 1 according to the present embodiment includes semiconductor elements 2, lead frames 3 that have conductivity and are connected to the semiconductor elements 2, the sealing resin 4 that seals the semiconductor elements 2 and the lead frame 3, and a heat conductive part 5 that has an insulation property and is formed of a ceramic compact.

Examples of the semiconductor elements 2 include diodes, semiconductor switching elements, and the like. FIG. 1 illustrates a case where the four semiconductor elements 2 are provided. The semiconductor element 2 is connected to the lead frame 3 with an unillustrated joining member such as a solder interposed therebetween.

The lead frame 3 is formed of, for example, a conductive metal. Note that, in the present embodiment, illustration of, for example, part of the lead frames 3 and part of the electrical wiring structures such as terminals of the semiconductor elements 2 are omitted.

Examples of the sealing resin 4 include a mold resin such as an epoxy resin.

The heat conductive part 5 is formed of a ceramic compact, and has a different structure from a structure that ceramic fillers are dispersed in a resin matrix. The heat conductive part 5 according to the present embodiment is entirely formed of the ceramic instead of fillers, so that, compared to a structure that ceramic fillers are dispersed in a resin matrix, it is possible to enhance the thermal conductivity, avoid problems caused by deterioration of flowability and filling property when fillers are added, and suppress production of voids.

Part of the heat conductive part 5 is sealed with the sealing resin 4, the heat conductive part 5 is connected to the lead frame 3 inside the sealing resin 4, and the other part of the heat conductive part 5 is exposed from the sealing resin 4. Consequently, heat generated in the semiconductor elements 2 can be radiated to the outside via the lead frames 3 and the heat conductive part 5.

The semiconductor device 1 according to the present embodiment includes a through-hole 6 that penetrates the sealing resin 4 and the heat conductive part 5. The through-hole 6 plays a role of a hole for attachment. Furthermore, the heat conductive part 5 is exposed from the sealing resin 4 inside the through-hole 6.

More specifically, as illustrated in FIG. 3, the heat conductive part 5 includes a cylindrical part 5A, and the inner circumference of the cylindrical part 5A is exposed from the sealing resin 4 inside the through-hole 6. Furthermore, the lower surface of the cylindrical part 5A is also preferably exposed from the sealing resin 4.

Furthermore, the heat conductive part 5 includes a plate-like part 5B that is connected to the outer circumferential side of the cylindrical part 5A, and is connected with the lead frames 3 with the plate-like part 5B interposed therebetween.

FIG. 3 illustrates as an example of a connection structure between the heat conductive part 5 and the lead frames 3 an example where the lead frames 3 include holes, the plate-like part 5B of the heat conductive part 5 includes a connection part 5C of a protruding shape, and the connection part 5C is press-fitted into the hole of the lead frame 3. Note that the connection structure is not limited thereto. For example, the hole of the lead frame 3 may be penetrated or may not be penetrated. Alternatively, screw structures may be provided to both of the heat conductive part 5 and the lead frames 3 to connect by screwing instead of press fitting. Furthermore, the structure may include a hole provided to the heat conductive part 5, and a connection part having a protruding shape and provided to the lead frame 3. Furthermore, the lead frame 3 and the connection part 5C may be connected by pinching one of the lead frame 3 and the connection part 5C by the other one thereof. Furthermore, the lead frame 3 and the connection part 5C may be connected by soldering or adhesion that uses an adhesive. Furthermore, the lead frame 3 and the connection part 5C may be connected by using any of press-fitting, pinching, and screwing in combination with any of soldering and adhesion that uses an adhesive.

Furthermore, the semiconductor device 1 according to the present embodiment includes outer leads 7 that have conductivity. The outer lead 7 is formed of, for example, a conductive metal. Part of the outer lead 7 is sealed with the sealing resin 4, the outer lead 7 is connected to the lead frame 3 inside the sealing resin 4, and the other part of the outer lead 7 is exposed from the sealing resin 4. The outer leads 7 play a role of external connection terminals. The outer leads 7 may be integrally formed with the lead frames 3. According to the structure according to the present embodiment, the lead frames 3 having the conductivity are not exposed from the sealing resin 4 except for the outer leads 7, so that it is possible to secure the insulation property and prevent corrosion of the lead frames 3.

FIG. 4 is a cross-sectional view illustrating a state where the semiconductor device according to Embodiment 1 has been attached.

The semiconductor device 1 according to the present embodiment can be attached to a heat dissipation member 10 by inserting a screw 11 into the through-hole 6. Examples of the heat dissipation member 10 include a heatsink and a housing. The heat dissipation member 10 has a screw structure. The screw 11 is preferably made of a material such as a metal having high thermal conductivity. The inner circumferential side of the cylindrical part 5A of the heat conductive part 5 preferably has a screw structure. The screw structure can increase a contact area between the cylindrical part 5A of the heat conductive part 5 and the screw 11 and improve adhesion therebetween, so that it is possible to enhance thermal conductivity. Gaps of an interface between the heat conductive part 5 and the screw 11, an interface between the heat conductive part 5 and the heat dissipation member 10, and an interface between the sealing resin 4 and the heat dissipation member 10 may be filled using a grease such as a silicone grease to ensure thermal conductivity. Note that, although a case where the heat dissipation member 10 has the screw structure is described as an example with reference to FIG. 4, the present disclosure is not limited thereto, and the heat dissipation member 10 may have a structure to be attached by additionally using an unillustrated nut disposed on a lower surface side of the heat dissipation member 10 in a case where the heat dissipation member 10 does not have the screw structure.

According to the present embodiment, heat generated in the semiconductor elements 2 can be radiated to the heat dissipation member 10 through the lead frames 3, the heat conductive part 5, and the screw 11. Furthermore, in a case where the lower surface of the cylindrical part 5A of the heat conductive part 5 is exposed from the sealing resin 4, it is also possible to radiate heat to the heat dissipation member 10 via this exposed portion.

As described above, according to the present embodiment, it is possible to implement the semiconductor device 1 having a high insulation property and heat dissipation performance.

### Embodiment 2

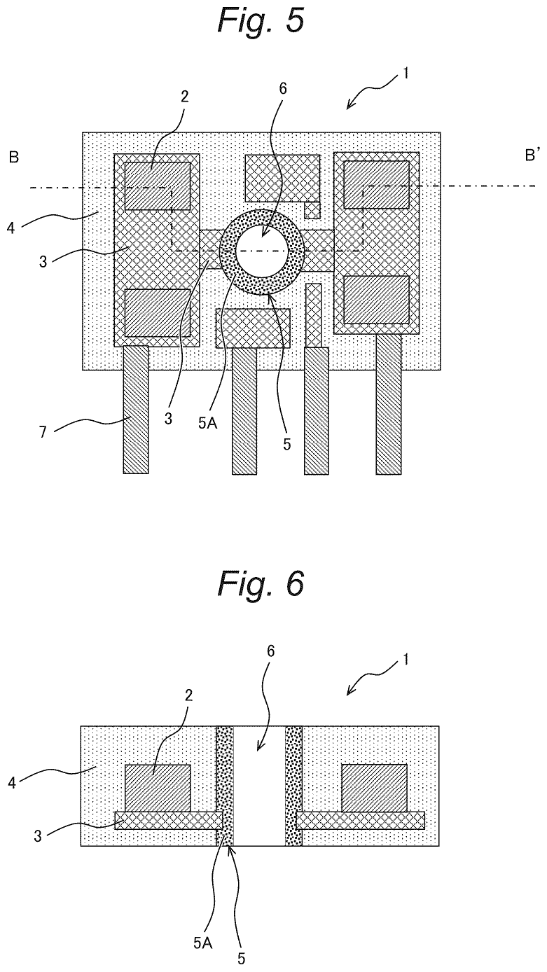

FIG. 5 is a top perspective view of the semiconductor device according to Embodiment 2. FIG. 6 is a cross-sectional view taken along line B-B′ in FIG. 5.

The present embodiment is an embodiment where the plate-like part 5B of the heat conductive part 5 according to Embodiment 1 is omitted, and the heat conductive part 5 is connected with the lead frames 3 on the outer circumferential side of the cylindrical part 5A.

Note that, although recess parts are provided on the outer circumferential side of the cylindrical part 5A to connect both of the heat conductive part 5 and the lead frames 3 by pinching the lead frames 3 in FIG. 6, the present disclosure is not limited thereto. Similarly to Embodiment 1, a structure can be adopted that the heat conductive part 5 and the lead frames 3 can be connected by any of press-fitting, pinching, screwing, soldering, and adhesion that uses an adhesive, or by using any of the press-fitting, the pinching, and the screwing in combination with any of the soldering and the adhesion that uses the adhesive.

In the present embodiment, the same effect can be obtained as in Embodiment 1.

### Embodiment 3

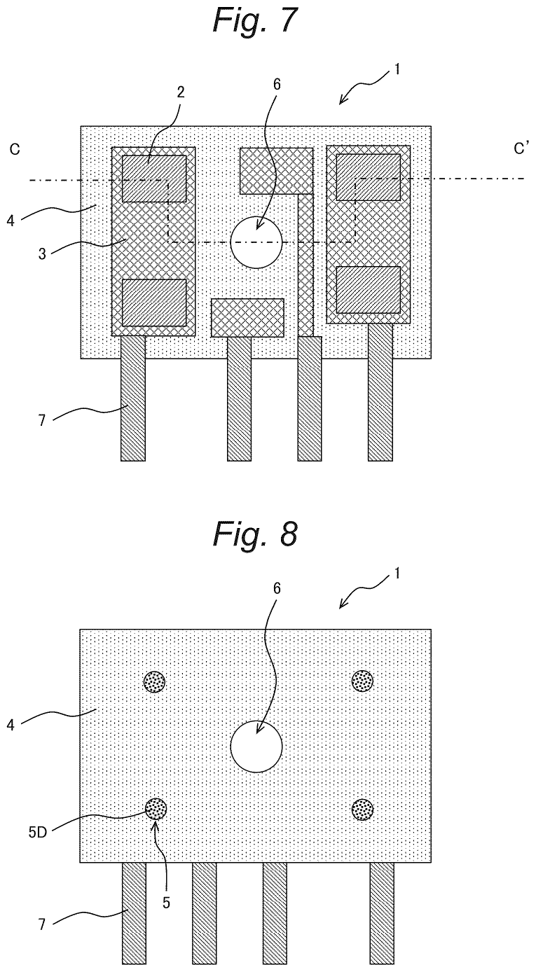

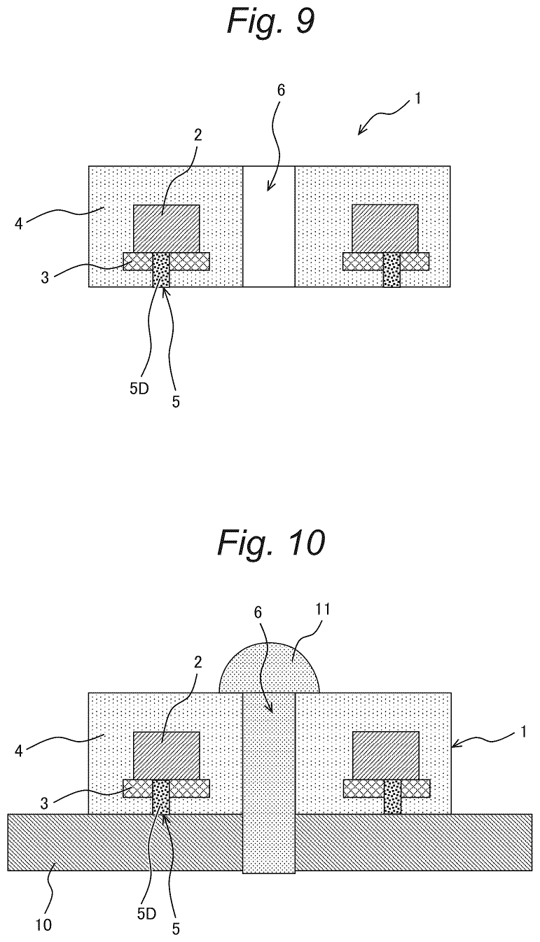

FIG. 7 is a top perspective view of the semiconductor device according to Embodiment 3. FIG. 8 is a back view of the semiconductor device according to Embodiment 3. FIG. 9 is a cross-sectional view taken along line C-C′ in FIG. 7.

The present embodiment is an embodiment where the heat conductive part 5 includes a columnar part 5D that is connected to the lead frame 3 at a position at which the heat conductive part 5 overlaps the semiconductor element 2, and is exposed from the sealing resin 4 at a position at which the other part of the heat conductive part 5 overlaps the semiconductor element.

According to the present embodiment, it is possible to shorten a route for heat dissipation, so that heat dissipation performance is high.

For the columnar part 5D, columnar members having various shapes such as columns having, for example, columnar shapes, prismatic shapes, elliptic columnar shapes, conical shapes, truncated conical shapes, spherical segment shapes, truncated pyramidal shapes, and constricted shapes can be used, and the shape thereof is not limited.

Furthermore, similarly to Embodiment 1, a structure can be adopted that the heat conductive part 5 and the lead frame 3 can be connected by any of press-fitting, pinching, screwing, soldering, and adhesion that uses an adhesive, or by using any of the press-fitting, the pinching, and the screwing in combination with any of the soldering and the adhesion that uses the adhesive. Furthermore, the side surfaces and the top surface of the heat conductive part 5 may be roughened to improve contact with the lead frame 3 and adhesion with the sealing resin 4 by the anchor effect.

FIG. 10 is a cross-sectional view illustrating a state where the semiconductor device according to Embodiment 3 has been attached.

Unlike Embodiment 1, the heat conductive part 5 does not include the cylindrical part 5A and the plate-like part 5B in the present embodiment. Accordingly, the through-hole 6 has a structure that penetrates the sealing resin 4. A screw structure may or may not be provided on the inner circumferential side of the through-hole 6 of the sealing resin 4. In a case where no screw structure is provided on the inner circumferential side of the through-hole 6 of the sealing resin 4, a process of forming the screw structure can be omitted.

Furthermore, there may be employed a configuration where the heat conductive part 5 includes a columnar part 5D that is connected to the lead frame 3 and is exposed from the sealing resin 4 on the face on which the other part of the heat conductive part 5 is attached to the heat dissipation member 10. In this case, although the heat conductive part 5 is preferably connected to the lead frame 3 at a position at which the heat conductive part 5 overlaps the semiconductor element 2, there may be employed a configuration where the heat conductive part 5 is connected to the lead frame 3 not at a position at which the heat conductive part 5 overlaps the semiconductor element 2, but at a position at which the heat conductive part 5 is as close as possible to the semiconductor element 2.

According to the present embodiment, it is possible to conduct heat generated in the semiconductor elements 2 to the heat conductive parts 5 directly or via the lead frames 3 and radiate the heat to the heat dissipation member 10 in a short distance.

### Embodiment 4

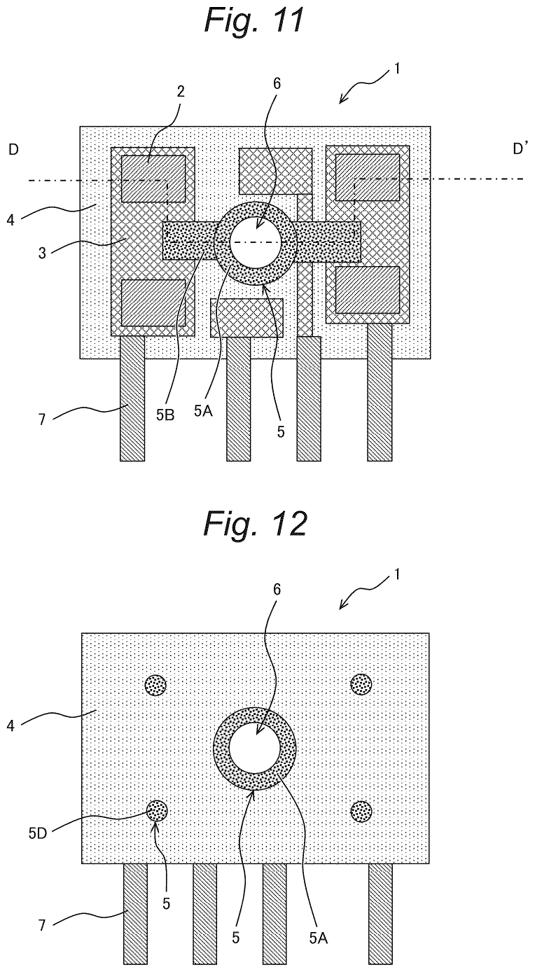

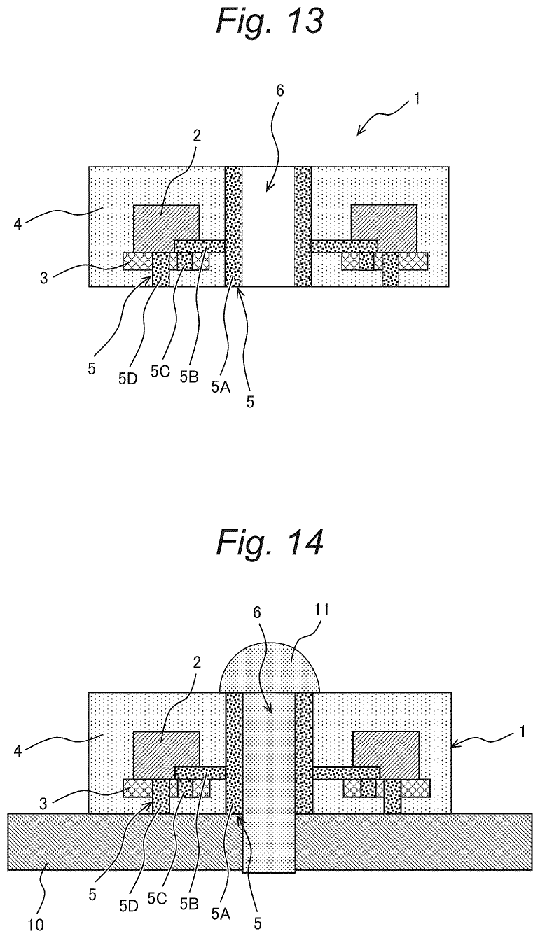

FIG. 11 is a top perspective view of the semiconductor device according to Embodiment 4. FIG. 12 is a back view of the semiconductor device according to Embodiment 4. FIG. 13 is a cross-sectional view taken along line D-D′ in FIG. 11. FIG. 14 is a cross-sectional view illustrating a state where the semiconductor device according to Embodiment 4 has been attached.

The present embodiment is an embodiment obtained by combining Embodiment 1 and Embodiment 3. According to the present embodiment, it is possible to obtain the same effect as those in Embodiment 1 and Embodiment 3. Note that the present disclosure is not limited thereto, and Embodiment 2 and Embodiment 3 may be combined.

While the embodiments of the present invention have been described above, the present invention is not limited to the configurations described in the embodiments, and various modifications can be made within the scope of the technical concepts of the present invention. In addition, some or all of the components described in the embodiments may be applied in combination.

### REFERENCE SIGNS LIST

1 Semiconductor device
2 Semiconductor element
3 Lead frame
4 Sealing resin
5 Heat conductive part
5A Cylindrical part
5B Plate-like part
5C Connection part
5D Columnar part
6 Through-hole
7 Outer lead
10 Heat dissipation member
11 Screw

1. A semiconductor device comprising:
a semiconductor element;
a lead frame that has conductivity and is connected to the semiconductor element;
a sealing resin that seals the semiconductor element and the lead frame;
a heat conductive part that has an insulation property and is formed of a ceramic compact, wherein
part of the heat conductive part is sealed with the sealing resin, the heat conductive part is connected to the lead frame inside the sealing resin, and other part of the heat conductive part is exposed from the sealing resin.

2. The semiconductor device according to claim 1, further comprising
a through-hole that penetrates the sealing resin and the heat conductive part, wherein
the other part of the heat conductive part is exposed from the sealing resin inside the through-hole.

3. The semiconductor device according to claim 2, wherein
the heat conductive part includes a cylindrical part, and an inner circumference of the cylindrical part is exposed from the sealing resin inside the through-hole.

4. The semiconductor device according to claim 3, wherein
the heat conductive part includes a plate-like part that is connected to an outer circumferential side of the cylindrical part, and is connected with the lead frame with the plate-like part interposed therebetween.

5. The semiconductor device according to claim 3, wherein
the heat conductive part is connected with the lead frame on an outer circumferential side of the cylindrical part.

6. The semiconductor device according to claim 1, wherein
the heat conductive part includes a columnar part that is connected to the lead frame at a position at which the heat conductive part overlaps the semiconductor element, and is exposed from the sealing resin at a position at which the other part overlaps the semiconductor element.

7. The semiconductor device according to claim 2, wherein
the heat conductive part includes a columnar part that is connected to the lead frame at a position at which the heat conductive part overlaps the semiconductor element, and is exposed from the sealing resin at a position at which the other part

8. The semiconductor device according to claim 1, wherein
the heat conductive part includes a columnar part that is connected to the lead frame and is exposed from the sealing resin on a face on which the other part is attached to the heat dissipation member.

9. The semiconductor device according to claim 2, wherein
the heat conductive part includes a columnar part that is connected to the lead frame and is exposed from the sealing resin on a face on which the other part is attached to the heat dissipation member.

10. The semiconductor device according to claim 1, wherein
the heat conductive part and the lead frame are connected by any of press-fitting, pinching, screwing, soldering, and adhesion that uses an adhesive, or by using any of the press-fitting, the pinching, and the screwing in combination with any of the soldering and the adhesion that uses the adhesive.
